(19) United States
(12) Patent Application Publication
(10) Pub. No.: US 2022/0351676 A1
(43) Pub. Date: Nov. 3, 2022

(54) OLED DISPLAYS WITH PRIVACY MODES

(71) Applicant: Hewlett-Packard Development Company, L.P., Spring, TX (US)

(72) Inventors: Hsing-Hung Hsieh, Taipei City (TW); Kuan-Ting Wu, Taipei City (TW); Dehuei Chen, Taipei City (TW)

(73) Assignee: Hewlett-Packard Development Company, L.P., Spring, TX (US)

(21) Appl. No.: 17/774,179

(22) PCT Filed: Nov. 18, 2019
(86) PCT No.: PCT/US2019/061935

§ 371 Date: May 4, 2022

(51) Int. Cl. G09G 3/3208; H01L 27/32; H01L 51/52

(52) U.S. Cl. CPC G09G 3/3208; H01L 27/3232; H01L 51/5271; H01L 51/5221; G09G 2358/00

(57) ABSTRACT

In example implementations, a display is provided. The display includes an organic light emitting diode (OLED). An anode is coupled to the OLED and a thin film transistor is coupled to the anode of the OLED. A cathode layer is coupled to the OLED. An electrically controllable reflective layer is coupled to the cathode layer. An electrode layer is coupled to the electrically controllable reflective layer to control an amount of reflectivity of the electrically controllable reflective layer.

### BACKGROUND

Displays can be used to produce visible images. Displays have evolved over time from cathode ray tube (CRT) based displays to light emitting diode (LED) based displays and organic LED (OLED) displays. The OLED displays provide a smaller and lighter display that is more energy efficient than CRT and LED based displays. OLED displays can also allow for a greater variety of form factors, shapes, and thinner sizes. For example, OLEDs can be used in flexible displays, ultra-thin displays, and the like.

OLED based displays can have a wide viewing angle as light is distributed at wide angles from the OLEDs. Emitting light at wide viewing angles may allow a user to see the display at a variety of viewing positions rather than having to sit directly in front of the display.

### BRIEF DESCRIPTION OF THE DRAWINGS

FIG. 1 is a block diagram of a cross-sectional view of an example display of the present disclosure;

FIG. 2 is a block diagram of another cross-sectional view of an example display of the present disclosure;

FIG. 3 is a block diagram of a top view of the display of the present disclosure;

FIG. 4 is a block diagram of an example viewing ranges of the sharing mode and the privacy mode of the present disclosure;

FIG. 5 is a flow chart of an example method for activating a privacy mode on a display the present disclosure; and

FIG. 6 is a block diagram of an example non-transitory computer readable storage medium storing instructions executed by a processor to activate a privacy mode on a display.

### DETAILED DESCRIPTION

Examples described herein provide OLED displays with privacy modes. As discussed above, some OLED based displays may have wide viewing angles. As a result, if a user is looking at sensitive information on the display, neighbors sitting next to the user may also view the display and see the sensitive information. Some users would like a privacy mode to prevent others from viewing information that is on the display.

Examples herein provide an OLED display that has switchable privacy modes. For example, a reflective layer may be placed over the OLEDs. The amount of reflectivity of the reflective layer may be controlled by an amount of current that is applied to the reflective layer. Thus, the higher the reflectivity of the reflective layer, the more collimated the light may be that is emitted by the OLEDs for a privacy mode. The lower the reflectivity of the reflective layer, the less collimated the light may be that is emitted by the OLEDs for a sharing mode.

In addition, the portions of the reflective layer over different color OLEDs may be independently controlled. As a result, the amount of color shift may be minimized when the privacy mode is activated.

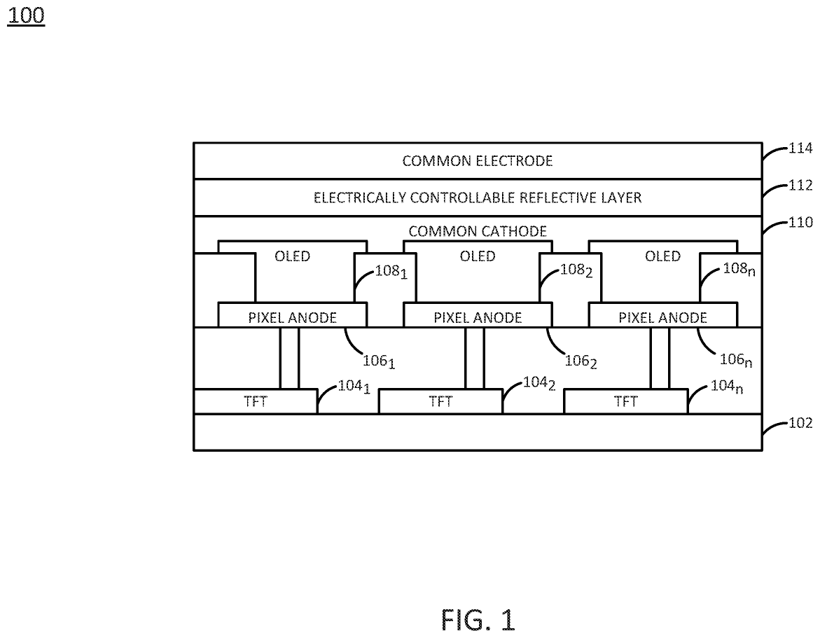

FIG. 1 illustrates a cross-sectional view of an example display 100 with an electrically controllable reflective layer 112 of the present disclosure. In an example, the display may include a substrate 102. The substrate 102 may be a glass panel for the display 100.

In an example, a plurality of thin film transistors (TFTs) 104₁ to 104ₙ (hereinafter also referred to individually as a TFT 104 or collectively as TFTs 104) may be formed on the substrate 102. For example, each pixel of the display 100 may be controlled by a respective TFT 104.

Anodes 106₁-106ₙ (hereinafter also referred to individually as an anode 106 or collectively as anodes 106) may be formed over the TFTs 104.

For example, an anode 106 may be formed over a respective TFT 104 to control a particular pixel. In an example, the anodes 106 may be communicatively coupled to the TFTs 104 with a conductive via.

In an example, a plurality organic light emitting diodes (OLEDs) 108₁-108ₙ (hereinafter also referred to individually as an OLED 108 or collectively as OLEDs 108) may be formed on the anodes 106. The OLEDs 108 may be formed from an organic compound (e.g., compounds that contain carbon) and may emit light in response to an electric current. The OLEDs 108 may be the same color or different colors.

In an example, a common cathode 110 may be part of a cathode layer that may be formed over the OLEDs 108. A power supply may be coupled to the display 100 to provide a current or voltage. The current may enter through the common cathode 110, travel through the OLEDs 108, and exit out of the anodes 106. The current flowing through the OLEDs 108 may cause the OLEDs 108 to emit light.

In an example, the electrically controllable reflective layer 112 may be formed over the common cathode 110. A common electrode 114 may be part of an electrode layer that may be formed over the electrically controllable reflective layer 112. The common cathode 110, the electrically controllable reflective layer 112, and the common electrode 114 may be fabricated to be optically clear. In other words, the common cathode 110, the electrically controllable reflective layer 112, and the common electrode 114 may be transparent or semi-transparent.

In an example, the electrically controllable reflective layer 112 may comprise layers of material that can change an amount of reflectivity of the layers when a current is applied to the layers of material. Current or voltage may be applied from the power supply coupled to the display 100 to flow through the electrically controllable reflective layer 112 via the common cathode 110 and the common electrode 114. Adjusting the reflectivity of the electrically controllable reflective layer 112 may change an angle at which light emitted by the OLEDs 108 may exit the electrically controllable reflective layer 112.

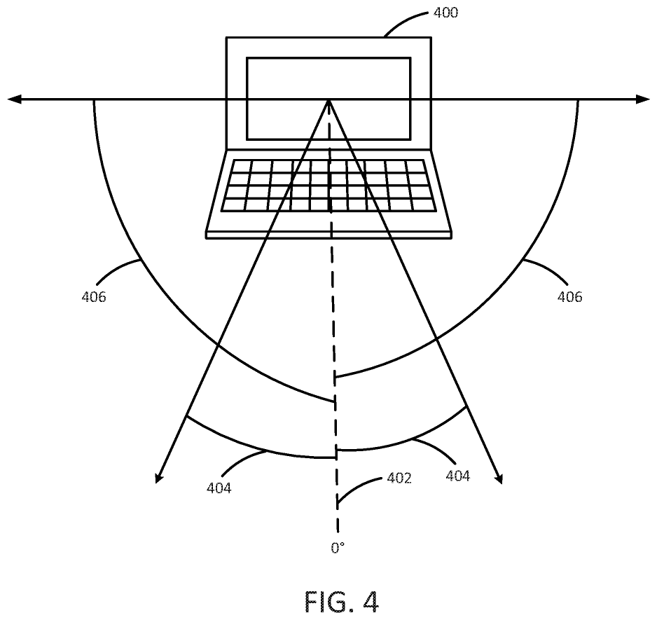

For example, when the amount of reflectivity of the electrically controllable reflective layer 112 is relatively high (e.g., greater than 50% and up to 99% of a surface area of the controllable reflective layer 112, or in one example approximately 99%), there may be a small area (e.g., less than 50% and down to 1% of a surface area of the controllable reflective layer 112, or in one example approximately 1%) at which the light emitted by the OLEDs 108 may be emitted through the electrically controllable reflective layer 112. The light may bounce internally between the electrically controllable reflective layer 112 and the pixel anode 106 until the light finds the small area to escape. Thus, the light emitted from the OLEDs 108 may be collimated. The collimated light may be associated with a privacy mode that allows narrow viewing angles (illustrated in FIG. 4 and discussed in further details below).

Conversely, when the amount of reflectivity of the electrically controllable reflective layer 112 is very low (e.g., 10%) there may be large areas at which the light emitted by the OLEDs 108 may be emitted through the electrically controllable reflective layer 112. Thus, the light emitted by the OLEDs 108 may escape through the electrically controllable reflective layer 112 in many directions. Light escaping in many directions may be associated with a sharing mode that allows wider viewing angles (illustrated in FIG. 4 and discussed in further details below).

In one example, the electrically controllable reflective layer 112 may be set to increase an amount of reflectivity with either increasing current or decreasing current based on a particular application. Either way, the electrically controllable reflective layer 112 may user current to change the amount of reflectivity to switch the display 100 between a privacy mode and a sharing mode.

In one example, the amount of current and how much the amount of reflectivity changes may be a function of the type of material used for the electrically controllable reflective layer 112. In an example, the electrically controllable reflective layer 112 may be a cholesteric liquid crystal (CLC) film. In an example, the electrically controllable reflective layer 112 may be a polymerized CLC film. The polymerized CLC film may be a layered structure that includes layers of liquid crystals and the polymerized cholesteric liquid crystals. The cholesteric liquid crystal molecules may be deposited down along with the layers. As such, the layers provide a reflective surface. When voltage or current is applied on the CLC film, the cholesteric liquid crystal molecules may rotate and become off-axis to the layers. As a result, the reflectivity may change because of the applied voltage or current.

In an example, the electrically controllable reflective layer 112 may be formed to have a thickness from a few microns (μm) to a few tens of μm. In an example, the thickness of the electrically controllable reflective layer 112 may be ranged from 5 μm to 20 μm.

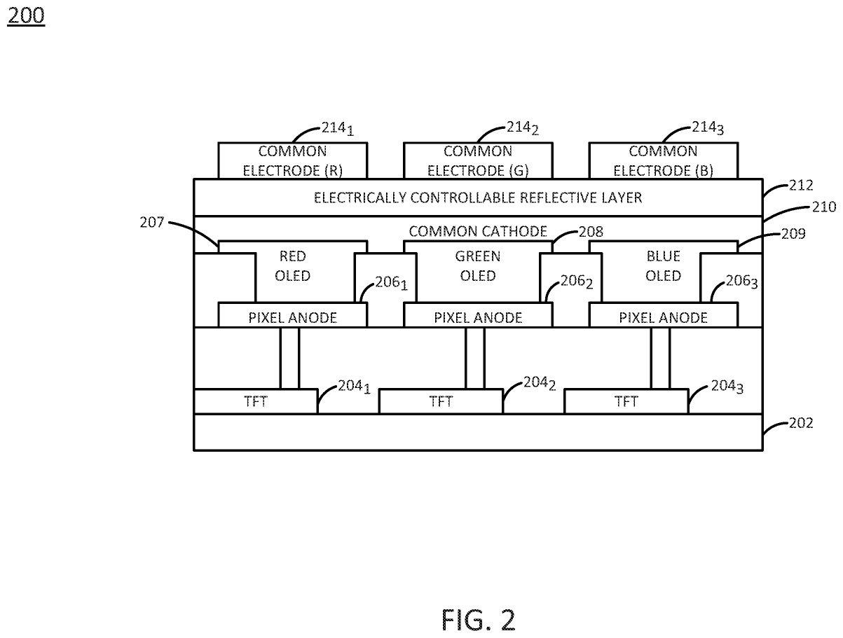

FIG. 2 illustrates a block diagram of a cross-sectional view of an example display 200 of the present disclosure. The display 200 may include a substrate 202, TFTs 204₁-204₃, and pixel anodes 206₁-206₃. The substrate 202, the TFTs 204₁-204₃, and the pixel anodes 206₁-206₃ may be similar to the substrate 102, the TFTs 104, and the pixel anodes 106 illustrated in FIG. 1, and discussed above.

The display 200 may be a red, green, blue (RGB) display. Thus, the display 200 may include a red OLED 207, a green OLED 208, and a blue OLED 209. The display 200 may also include a common cathode 210 (e.g., similar to the common cathode 110 illustrated in FIG. 1, and discussed above). Thus, the display 200 may have the red OLED 207 formed over the pixel anode 206₁ and the TFT 204₁, the green OLED 208 formed over the pixel anode 206₂ and the TFT 204₂, and the blue OLED 209 formed over the pixel anode 206₃ and the TFT 204₃.

The display 200 may include an electrically controllable reflective layer 212. The electrically controllable reflective layer 212 may be a polymerized CLC film and function similar to the electrically controllable reflective layer 112 illustrated in FIG. 1, and discussed above.

In an example, the display 200 may include a plurality of common electrodes 214₁, 214₂, and 214₃. The common electrode 214₁ may be located over a portion of the electrically controllable reflective layer 212 that is located over the red OLED 207. The common electrode 214₂ may be located over a portion of the electrically controllable reflective layer 212 that is located over the green OLED 208. The common electrode 214₃ may be located over a portion of the electrically controllable reflective layer 212 that is located over the blue LED 209.

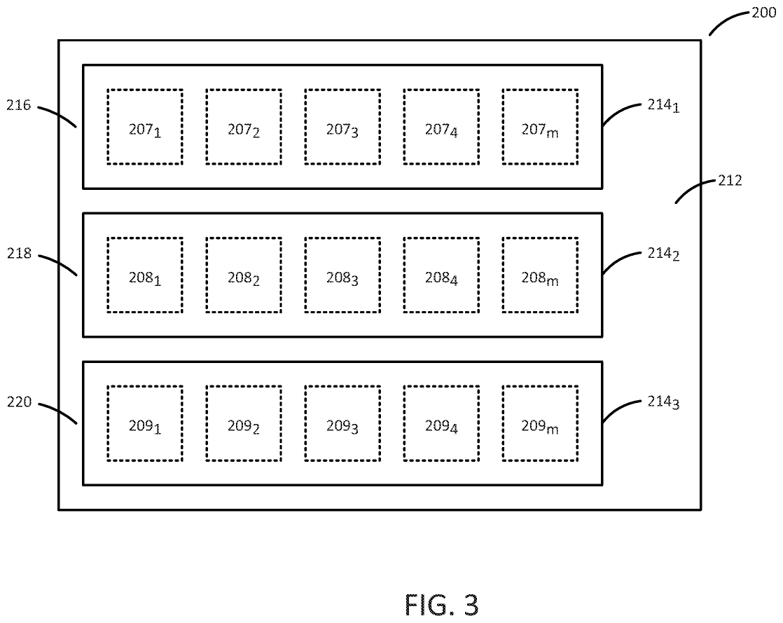

FIG. 3 illustrates a top view of the display 200. In an example, the red OLED 207 may include a plurality of red OLEDs 207₁-207ₘ arranged as an array of red OLEDs 207₁-207ₘ. The common electrode 214₁ may be located on a portion 216 of the electrically controllable reflective layer 212 that is located over the array of red OLEDs 207₁-207ₘ.

Similarly, the green OLED 208 may include a plurality of green OLEDs 208₁-208ₘ and the blue OLED 209 may include a plurality of blue OLEDs 209₁-209ₘ. The green OLEDs 208₁-208ₘ may be arranged as an array and the blue OLEDs 209₁-209ₘ may be arranged as an array. The common electrode 214₂ may be located on a portion 218 of the electrically controllable reflective layer 212 that is located over the array of green OLEDs 208₁-208ₘ The common electrode 214₃ may be located on a portion 220 of the electrically controllable reflective layer 212 that is located over the array of blue OLEDs 209₁-209ₘ. Although three common electrodes 214₁-214₃ are illustrated in FIGS. 2 and 3, it should be noted that the display 200 may include any number of common electrodes. For example, each array of OLEDs may be associated with a respective common electrode.

The separate common electrodes 214₁-214₃ may allow different amounts of current or voltage to be applied to the different portions 216, 218, and 220 of the electrically controllable reflective layer 212. The amount of current or voltages may adjust the amount of reflectivity for the different portions 216, 218, and 220 to be controlled to coincide with a wavelength of a respective color of the red OLED 207, the green OLED 208, and the blue OLED 209.

For example, the red OLED 207 may emit light at a first wavelength, the green OLED 208 may emit light at a second wavelength, and the blue OLED 209 may emit light at a third wavelength. The common electrode 214₁ may apply a first amount of current to the portion 216 of the electrically controllable reflective layer 212 such that the amount of reflectivity adjusts light emitted by the red OLED 207 at the first wavelength at a desired viewing angle. The common electrode 214₂ may apply a second amount of current to the portion 218 of the electrically controllable reflective layer 212 such that the amount of reflectivity adjusts light emitted by the green OLED 208 at the second wavelength at the desired viewing angle. The common electrode 214₃ may apply a third amount of current to the portion 220 of the electrically controllable reflective layer 212 such that the amount of reflectivity adjusts the light emitted by the blue OLED 209 at the third wavelength at the desired viewing angle.

In other words, the common electrodes 214₁-214₃ may apply different amounts of currents to the different portions 216, 218, and 220 of the electrically controllable reflective layer 212 to achieve the same desired viewing angle for the different colored OLEDs 207, 208, and 209. Said yet another way, the different portions 216, 218, and 220 electrically controllable reflective layer 212 may be controlled to have different amounts of reflectivity to adjust for the different wavelengths of light emitted by the different colored OLEDs 207, 208, and 209 to achieve the same desired viewing angle across the different colored OLEDs 207, 208, and 209.

In an example, the different portions 216, 218, and 220 of the electrically controllable reflective layer 212 may include different materials. For example, the different portions 216, 218, and 220 may include different formulations of the polymerized CLC film (e.g., different polymers, different monomers, different amounts of the polymers, and the like mixed with the CLC). The different materials may have different amounts of reflectivity at different amounts of currents in accordance with the wavelengths of the light emitted by the different colored OLEDs 207, 208, and 209.

Controlling the amount of reflectivity differently on the different portions 216, 218, and 220 of the electrically controllable reflective layer 212 for different colored OLEDs may improve color performance of the display 200 when operated in a privacy mode. For example, applying different amounts of current to the different portions 216, 218, and 220 of the electrically controllable reflective layer 212 may provide zero, or near zero, color shift between a privacy mode (e.g., narrow viewing angles) and a sharing mode (e.g., wide viewing angles).

Thus, the display 100 and the display 200 may provide a way to enable a privacy mode and a sharing mode for displays that use OLEDs. In addition, the display 100 and the display 200 provide a way to enable a privacy mode and a sharing mode with minimum impact to the existing device architecture, pixel circuit, and fabrication process.

FIG. 4 illustrates an example of the viewing ranges of the sharing mode and the privacy mode of the present disclosure. FIG. 4 illustrates an apparatus 400. For example, the display of the apparatus 400 may be the display 100 or 200 illustrated in FIGS. 1-3 above. In one example, the apparatus 400 may be a laptop computer, a tablet computer, or a monitor.

In one example, the viewing angles may be defined relative to a person who is sitting in front of the apparatus 400 and centered to the apparatus 400 at an angle of 0 degrees as illustrated by line 402. In one example, the line 402 may be a central light emitting axis of the display. In one example, the viewing angles may be defined relative to either side of a central light emitting axis of each OLED 108 through the electrically controllable reflective layer 112 or the red OLEDs 207, green OLEDs 208, and blue OLEDs 209 through the electrically controllable reflective layer 212.

In one example, the angles 404 on either side of the line 402 may define the viewing angles in the privacy mode. The angles 404 may be relatively narrow such that individuals who are viewing the display of the apparatus 400 outside of the angles 404 cannot view the display of the apparatus 400.

In one example, the angles 404 may be approximately 15 degrees to 45 degrees to either side of the line 402. For example, the angles 404 could be +/−15 degrees to +/−45 degrees. Said another way, the total viewing angle may be approximately a total of 30 degrees to 90 degrees. In one example, the angles 404 may be approximately +/−25 degrees to +/−35 degrees. In one example, the angles 404 may be approximately +/−30 degrees.

In one example, the angles 406 on either side of the line 402 may define the viewing angles in the sharing mode. The angles 406 may be relatively wide such that individuals who are viewing the display of the apparatus 400 within the angles 406 may be able to view the display of the apparatus 400.

In one example, the angles 406 may be approximately 45 degrees to 90 degrees to either side of the line 402. For example, the angles 406 could be +/−45 degrees to +/−90 degrees. Said another way, the total viewing angle may be approximately a total of 90 degrees to 180 degrees. In one example, the angles 406 may be +/−55 degrees to +/−80 degrees. In one example, the angles 406 may be +/−65 degrees to +/−70 degrees.

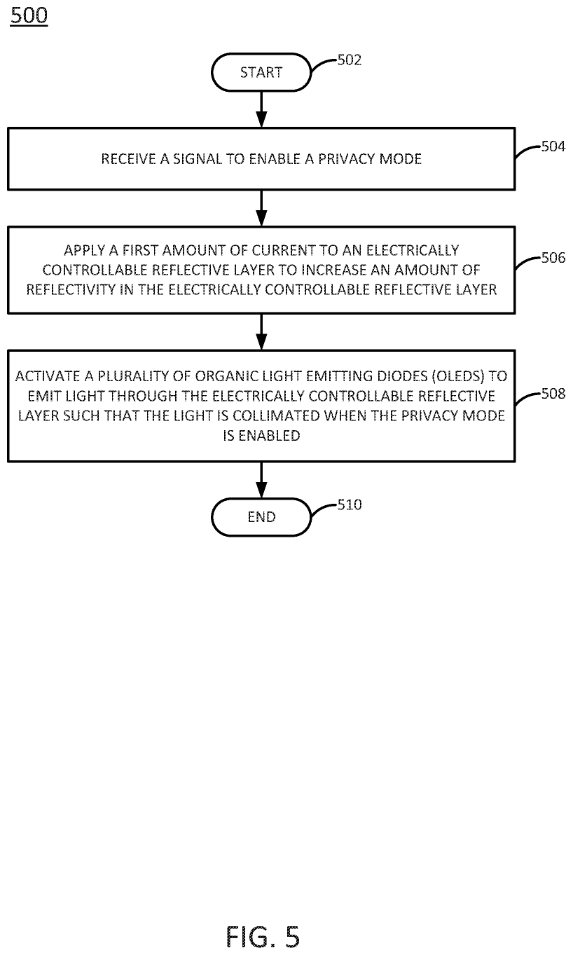

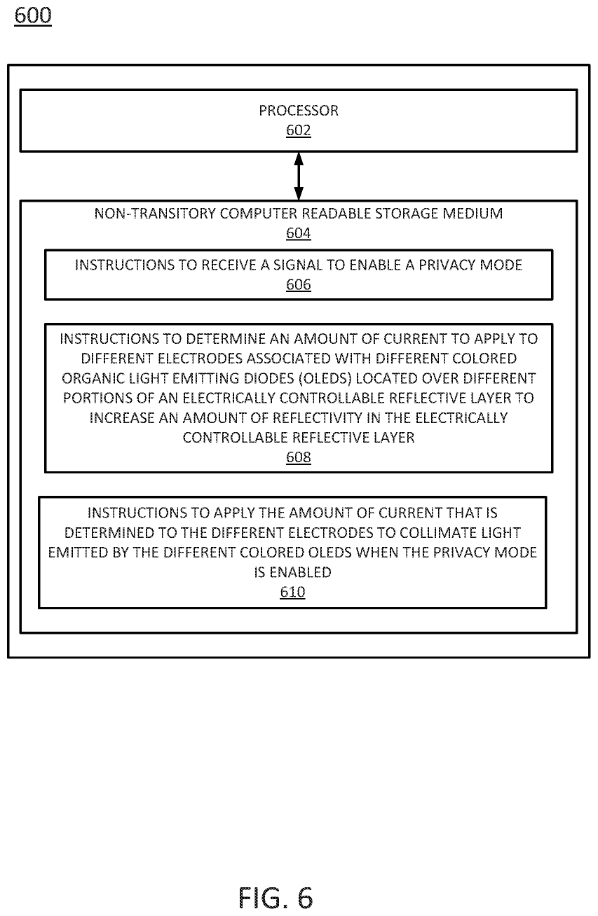

FIG. 5 illustrates a flow diagram of an example method 500 for activating a privacy mode on a display the present disclosure. In an example, the method 500 may be performed by the display 100, the display 200, the apparatus 400, or the apparatus 600 illustrated in FIG. 6 and described below.

At block 502, the method 500 begins. At block 504, the method 500 receives a signal to enable a privacy mode. For example, a display may include a physical button or a menu selection on a graphical user interface that allows a user to toggle between a privacy mode and a sharing mode. The privacy mode may enable a mode that causes the light emitted by the display to be collimated into narrow viewing angles. The sharing mode may cause the display to emit light at wide viewing angles.

At block 506, the method 500 applies a first amount of current to an electrically controllable reflective layer to increase an amount of reflectivity in the electrically controllable reflective layer. Increasing the amount of reflectivity may change a viewing angle of the light emitted by the organic light emitting diodes (OLEDs) of the display. For example, a high amount of reflectivity may cause the electrically controllable reflective layer to have a small area in which the light may escape at a fixed viewing angle associated with the small area. As a result, most of the light emitted by the OLEDs may escape through the same area and, as a result, be collimated to narrow viewing angles.

In an example, a plurality of electrodes may be located over different colored organic light emitting diodes (OLEDs) of the display. The amount of current that is applied to each of the electrodes may be a function of a wavelength of the color of light emitted by the OLEDs associated with the electrode.

For example, for an RGB display, a first electrode may be located over the portion of the electrically controllable reflective layer that is over an array of red OLEDs. A second electrode may be located over the portion of the electrically controllable reflective layer that is over an array of green OLEDs. A third electrode may be located over the portion of the electrically controllable reflective layer that is over an array of blue OLEDs. The amount of current applied to the first electrode may be a function of the wavelength of the light emitted by the red OLEDs, the amount of current applied to the second electrode may be a function of the wavelength of the light emitted by the green OLEDs, and the amount of current applied to the third electrode may be a function of the wavelength of the light emitted by the blue OLEDs.

At block 508, the method 500 activates a plurality of organic light emitting diodes (OLEDs) to emit light through the electrically controllable reflective layer such that the light is collimated when the privacy mode is enabled. When different colored OLEDs are used, the different electrodes may cause the reflectivity of different portions of the electrically controllable reflective layer to have different amounts of reflectivity based on the color of the OLEDs. This may minimize the color shift when toggling between the privacy mode and sharing mode.

In an example, a signal to disable the privacy mode may be received. For example, a sharing mode may be selected via a physical button or a menu selection on a graphical user interface on the display. A second amount of current may be applied to the electrically controllable reflective layer, or the current may be removed, to decrease the amount of reflectivity in the electrically controllable reflective layer. The OLEDs may then be activated to emit light through the electrically controllable reflective layer such that the light is not collimated. For example, the light may be emitted at wide viewing angles in the sharing mode. At block 510, the method 500 ends.

FIG. 6 illustrates an example of an apparatus 600. In an example, the apparatus 600 may be the display 100 or 200. In an example, the apparatus 600 may include a processor 602 and a non-transitory computer readable storage medium 604. The non-transitory computer readable storage medium 604 may include instructions 606, 608, and 610 that, when executed by the processor 602, cause the processor 602 to perform various functions.

In an example, the instructions 606 may include instructions to receive a signal to enable a privacy mode. The instructions 608 may include instructions to determine an amount of current to apply to different electrodes associated with different colored organic light emitting diodes (OLEDs) located over different portions of an electrically controllable reflective layer to increase an amount of reflectivity in the electrically controllable reflective layer. The instructions 610 may include instructions to apply the amount of current that is determined to the different electrodes to collimate light emitted by the different colored OLEDs when the privacy mode is enabled.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. A display for an electronic device, comprising:
an organic light emitting diode (OLED);
an anode coupled to the OLED;
a thin film transistor coupled to the anode of the OLED;
a cathode layer coupled to the OLED;
an electrically controllable reflective layer coupled to the cathode layer; and
an electrode layer coupled to the electrically controllable reflective layer to control an amount of reflectivity of the electrically controllable reflective layer.

2. The display of claim 1, wherein the electrically controllable reflective layer comprises a polymerized cholesteric liquid crystal film.

3. The display of claim 1, wherein the OLED comprises a plurality of OLED arrays, wherein the plurality of OLED arrays comprises a red OLED array, a green OLED array, and a blue OLED array.

4. The display of claim 3, wherein the electrode layer comprises a plurality of independently controllable electrode layers, wherein red OLED array is associated with a first one of the plurality of independently controllable electrode layers, the green OLED array is associated with a second one of the plurality of independently controllable electrode layers, and the blue OLED array is associated with a third one of the plurality of independently controllable electrode layers.

5. The display of claim 1, wherein the cathode layer and the electrode layer are transparent or semi-transparent.

6. The display of claim 1, wherein a first amount of current applied to the electrically controllable reflective layer causes the electrically controllable reflective layer to have a first amount of reflectivity associated with a privacy mode.

7. The display of claim 6, wherein a second amount of current applied to the electrically controllable reflective layer causes the electrically controllable reflective layer to have a second amount of reflectivity associated with a sharing mode, wherein the second amount of reflectivity is less than the first amount of reflectivity.

8. A method, comprising:
receiving, by a processor, a signal to enable a privacy mode;
applying, by the processor, a first amount of current to an electrically controllable reflective layer to increase an amount of reflectivity in the electrically controllable reflective layer; and
activating, by the processor, a plurality of organic light emitting diodes (OLEDs) to emit light through the electrically controllable reflective layer such that the light is collimated when the privacy mode is enabled.

9. The method of claim 8, further comprising:
receiving, by the processor, a signal to disable the privacy mode;
applying, by the processor, a second amount of current to the electrically controllable reflective layer to decrease the amount of reflectivity in the electrically controllable reflective layer; and
activating, by the processor, the plurality of OLEDs to emit light through the electrically controllable reflective layer such that the light is not collimated when the privacy mode is disabled.

10. The method of claim 8, wherein a first electrode associated with red color OLEDs is located over a first portion of the electrically controllable reflective layer, a second electrode associated with green color OLEDs is located over a second portion of the electrically controllable reflective layer, and a third electrode associated with blue color OLEDs is located over a third portion of the electrically controllable reflective layer.

11. The method of claim 10, wherein an amount of current that is applied is different for the first electrode, the second electrode and the third electrode.

12. The method of claim 11, wherein the amount of current that is applied to the first electrode, the second electrode, and the third electrode is a function of a wavelength of light emitted by the red color OLEDs, green color OLEDs, and the blue color OLEDs.

13. A non-transitory computer readable storage medium encoded with instructions executable by a processor, the non-transitory computer-readable storage medium comprising:
instructions to receive a signal to enable a privacy mode;
instructions to determine an amount of current to apply to different electrodes associated with different colored organic light emitting diodes (OLEDs) located over different portions of an electrically controllable reflective layer to increase an amount of reflectivity in the electrically controllable reflective layer;
instructions to apply the amount of current that is determined to the different electrodes to collimate light emitted by the different colored OLEDs when the privacy mode is enabled.

14. The non-transitory computer readable storage medium of claim 13, wherein the different colored OLEDs comprise a red colored OLED, a green colored OLED, and a blue colored OLED and the instructions to determine, further comprises:
instructions to determine a first amount of current to apply a first electrode coupled to a first portion of the electrically controllable reflective layer located over the red colored OLED;
instructions to determine a second amount of current to apply to a second electrode coupled to a second portion of the electrically controllable reflective layer located over the green colored OLED; and
instructions to determine a third amount of current to apply to a third electrode coupled to a third portion of the electrically controllable reflective layer located over the blue colored OLED.

15. The non-transitory computer readable storage medium of claim 13, wherein the amount of reflectivity of the first portion, the second portion, and the third portion of the electrically controllable reflective layer is different.
